(19) United States
(12) Patent Application Publication
(10) Pub. No.: US 2006/0105567 A1
(43) Pub. Date: May 18, 2006

(54) Method for forming a dual-damascene structure

(75) Inventors: Vijayakomar S. Ramachandrarao, Portland, OR (US); Kevin P. O'Brien, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 10/987,780

(22) Filed: Nov. 12, 2004

(51) Int. Cl. H01L 21/4763

(52) U.S. Cl. 438/637

(57) ABSTRACT

A dual-damascene structure is formed in a porous dielectric material using an anti-reflective coating. In accordance with one embodiment, during patterning and etching if the trench portions of the dual-damascene structure, the anti-reflective coating has a first density. After patterning and etching, the anti-reflective coating density is reduced. The reduction in the anti-reflective coating's density facilitates selective removal of the anti-reflective coating relative to the porous dielectric material.

### FIELD OF THE INVENTION

Embodiments of the present invention relate generally to semiconductor manufacturing and more specifically, to methods for forming semiconductor device interconnects.

### BACKGROUND OF THE INVENTION

One approach for forming dual-damascene interconnects is via-first patterning. To successfully integrate this approach, the etch selectivity between the interlevel dielectric (ILD) and the underlying etch stop layer (ESL) should be high and to the extent possible, substrate reflectively during trench lithographic patterning should be minimized.

One method for addressing these needs includes forming a Sacrificial Light Absorbing Material (SLAM) over the ILD and in the via prior to patterning the trench. The SLAM, which absorbs light and has an etch rate that is comparable to the ILD, functions as an antireflective coating (ARC) for trench patterning and as an etch buffer that protects the ESL during the via and trench etches, thereby reducing the ESL selectivity requirements. After the trench is etched, the SLAM is removed using wet or dry etching/cleaning processes, or combinations thereof.

To facilitate SLAM removal after trench etch, the SLAM etch rate should be greater than the ILD etch rate. With conventional ILDs, such as chemical vapor deposition (CVD) silicon dioxide based dielectrics, SLAM removal is relatively easy because the SLAM, which is spun-on, has a higher microporosity than the conventional ILD and is less dense. Films that are less dense generally etch faster and can therefore be removed selectively with respect to denser films. However, low dielectric constant (low-k) materials, ultra low-k materials, and mesoporous dielectric materials (i.e., dielectric materials having an average pore size ranging from about 2-50 nanometers), which are being considered for next generation integrated circuits, can be less dense than conventional ILDs. They are therefore more prone to chemical attack during SLAM removal. Consequently, the integration of many of these ILDs with SLAM processing will not be seamless and etch rates and selectivities of the two materials must be considered. One possible option for addressing integration considerations is to develop a new class of clean processes that are capable of selectively removing SLAMs in the presence of porous dielectrics. However, this option is proving to be difficult and expensive.

### BRIEF DESCRIPTION OF THE DRAWINGS

FIGS. 1-8 illustrate, in cross-sectional diagrams, a method for incrementally forming a dual-damascene structure in accordance with an embodiment of the present invention;

FIG. 9 illustrates a cross-sectional diagram of the dual-damascene structure of FIG. 8 after filling it with an interconnect material; and

FIG. 10 illustrates, in a flow chart, a method for forming a dual-damascene interconnect structure in accordance with one embodiment of the present specification.

It will be appreciated that for simplicity and clarity of illustration, elements in the drawings have not necessarily been drawn to scale. For example, the dimensions of some of the elements may be exaggerated relative to other elements for clarity. Further, where considered appropriate, reference numerals have been repeated among the drawings to indicate corresponding or analogous elements.

### DETAILED DESCRIPTION

In the following detailed description, a method for forming semiconductor damascene structures is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

In accordance with one embodiment, a method for forming a semiconductor device is disclosed wherein an ARC is formed over a substrate. The ARC is used to define a pattern in a resist layer. A feature defined by the pattern is etched. A property of the ARC is changed. And then, the ARC is removed. In one embodiment, the ARC is a SLAM. In one embodiment, the ARC property changed is its density. Density can be changed by incorporating a porogen agent (an agent used to generate porosity in a material) into the ARC prior to depositing it on the substrate.

In one embodiment a porous ILD is formed over the substrate prior to forming the ARC. A first opening is formed in the ILD. The ARC substantially fills the first opening and covers portions of the ILD's top surface. Resist is pattered over the ARC and then portions of the ARC and ILD are etched to form a second opening. In one embodiment, forming a first opening forms via portions of a dual-damascene opening and forming a second opening forms trench portions of the dual-damascene opening. After the dual-damascene opening is formed, it can be filled with conductive material to form a dual-damascene interconnect structure.

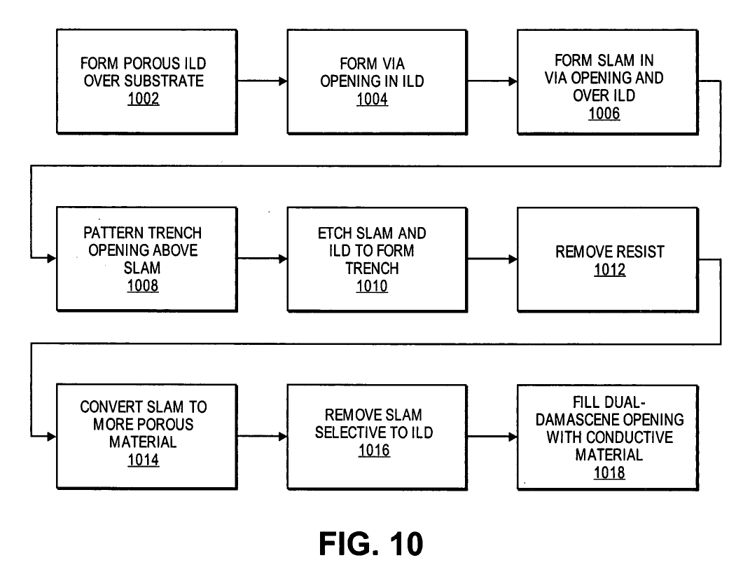

Shown in FIG. 10, is a flow diagram illustrating a series of processing steps that can be used to form a dual-damascene structure in accordance with one embodiment of the present invention. First as shown in 1002, a dielectric layer, such as a porous ILD, or the like is formed over a semiconductor substrate. Then, in 1004, a via opening is patterned in the ILD. In 1006, a SLAM is deposited in the via opening and over the upper (top) surface of the dielectric. In 1008, a resist layer is patterned to define a trench opening above the SLAM. In 1010, the SLAM and portions of the ILD are etched to define a trench opening in the ILD above the via. In 1012, the resist is removed. In 1014, the SLAM is converted to a more porous version to facilitate its selective removal relative to the porous ILD. In 1016, the SLAM is removed and a dual-damascene opening is thereby formed in the ILD. And, in 1018, the dual-damascene opening is filled with conductive materials to form a dual-damascene interconnect structure.

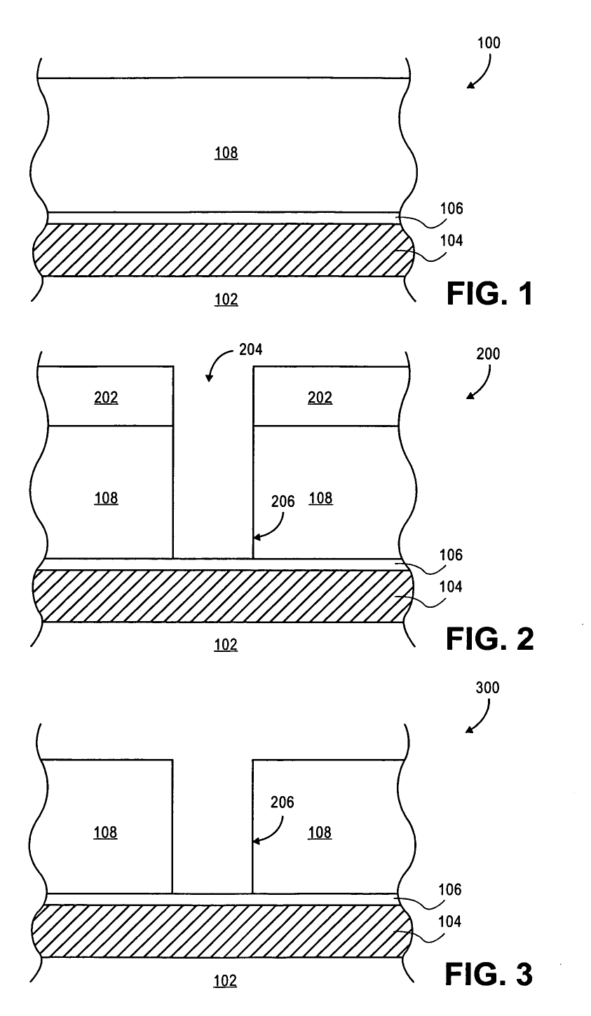

FIGS. 1-8 illustrate, in cross-sectional diagrams, formation of a dual-damascene interconnect structure in accordance with an embodiment of the present invention. FIG. 1 illustrates a partially fabricated semiconductor device 100. The semiconductor device 100 includes one or more base layers 102. Under the base layers 102 is a substrate which is preferably a semiconductor wafer. The substrate material can be silicon, silicon germanium, gallium arsenide or other III-V compounds, silicon carbide, silicon on insulator (SOI), or the like.

Over the substrate is formed the multi-layered region 102 of FIG. 1. Region 102 typically includes a combination of dielectric, semiconductive, and/or conductive layers that have been photolithographically patterned and etched to form semiconductor device structures over, on, or within the substrate. For example, region 102 may include one or more of various dielectric layers such as silicon nitride, silicon dioxide, tetraethylorthosilicate (TEOS), borophosphosilicate glass (BPSG), spin on glass (SOG), low-k materials, or the like. The region 102 may also contain semiconductive features that may include one or more of epitaxial silicon, polysilicon, amorphous silicon, doped polysilicon, or the like. In addition, the multi-layer region 102 can also include conductive features or metallic layers that include one or more of refractory silicides, refractory metals, aluminum, copper, alloys of these materials, conductive nitrides, conductive oxides, or the like.

Overlying region 102 is a conductive structure 104. The conductive structure 104 can be an interconnect, conductive plug, or the like. The conductive structure 104 can include adhesion layers, barrier layers, seed layers and conductive fill materials formed from materials that include refractory silicides, refractory metals, aluminum, copper, alloys of these materials, conductive nitrides, conductive oxides, or the like. Conductive structure 104 may be electrically connected to some portions of region 102 and electrically insulated from other portions of region 102.

Overlying the conductive structure 104 is an optional etch stop layer (ESL) 106. The etch stop layer 106 typically, but not necessarily, includes one or more of titanium nitride, silicon nitride, silicon oxynitride, or a silicon-rich-silicon-nitride. The etch stop layer can be deposited using chemical vapor deposition (CVD) or physical vapor deposition (PVD).

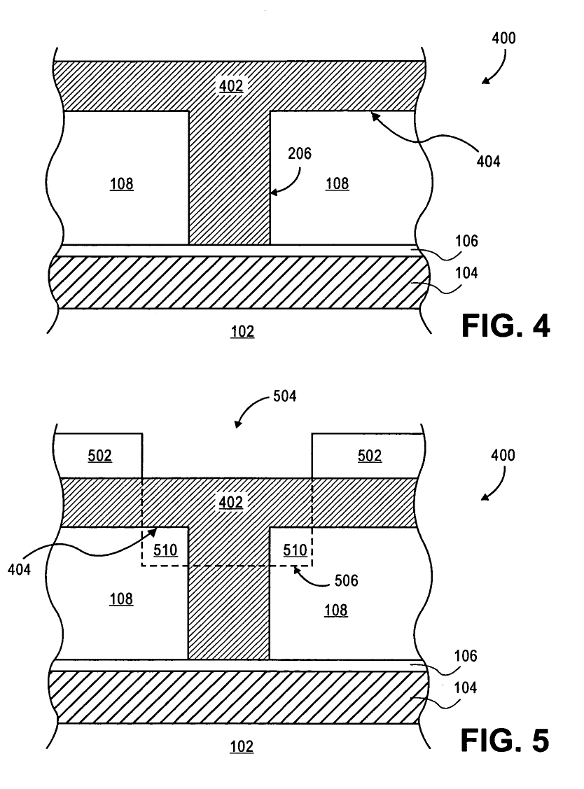

Over the etch stop layer 106 is an interlevel dielectric (ILD) 108. In accordance with one embodiment, the ILD 108 is a porous dielectric material. Porous ILDs can include low-k dielectrics, ultra low-k dielectrics, mesoporous dielectrics, or any dielectric material having an intrinsic density that is close to or less than the density of a SLAM, which will subsequently be formed over ILD 108 (SLAM formation is discussed with respect to FIGS. 4-7). For the purpose of this specification, a low-k dielectric is one having a dielectric constant lower than that of silicon dioxide (i.e. approximately 3.9). For the purpose of this specification, an ultra low-k dielectric is one in which the dielectric constant of a low-k material has been further decreased by the making it more porous. Specific examples of porous dielectric materials include spin-on carbon doped oxides, such as hydroxysilesquioxane-based porous carbon doped oxides, methylsilesquioxane-based porous carbon doped oxides, chemical vapor deposition-based porous carbon doped oxides, hot filament vapor deposited low-k dielectric constant doped oxides, spin-on doped siloxanes, porous diamond low-k materials, or the like. The ILD 108 can be deposited using CVD, plasma enhanced CVD (PECVD), spin-on methods, or the like.

FIGS. 2 and 3 illustrates that the ILD 108 has been lithographically patterned to form via opening 206. FIG. 2 shows a resist layer 202 formed over the top surface of the ILD 108 (although not shown here, in alternative embodiments, intervening layers, such as hardmask layers, protective layers, etc., may be disposed between the resist layer and the ILD 108). The resist layer 202 has been patterned to form a first opening 204. Portions of the ILD 108 exposed by the opening 204 can be removed using a conventional anisotropic etch process (for example, in those cases where the ILD 108 is an inorganic silicon and oxygen containing material, using a fluorine-containing plasma etch process, or in those cases where the ILD 108 is a polymer, using an oxygen-containing plasma etch process) to form via opening 206. As shown in FIGS. 2 and 3, etching to form via opening 206 typically terminates on or in the etch stop layer 106 (or on the underlying conductive layer in the absence of the etch stop layer). FIG. 3 further illustrates the cross-section shown in FIG. 2 after removing the resist layer 202. Resist is removed using conventional wet or dry resist removal processes.

Turning now to FIG. 4, an antireflective/fill material 402 is formed overlying the upper surface (top side) 404 of the ILD 108 and within via opening 206. In accordance with one embodiment, the antireflective/fill material 402 is formulated in such a way as to allow physical properties, chemical properties, or combinations thereof to be changed after it has been deposited to thereby make its removal easier. The antireflective/fill material 402 preferably (but not necessarily) (1) has a high optical absorption at the exposure wavelength used during lithography process to define the trench patterns, (2) uniformly fills the via opening 206 and has an etch rate that is comparable to the ILD etch rate, (3) has good selectivity to the photoresist during the trench etch process, and (4) is compatible with the trench lithographic process (i.e., the trench photoresist coat, patterning, developing, or cleaning processes). The antireflective/fill material 204 can be an inorganic ARC/fill material, an organic ARC/fill material, portions of a bi-layered or tri-layered resist, or the like. The antireflective/fill material 402 can be spun-on or it can be deposited using chemical vapor deposition processes.

In one embodiment the antireflective/fill material 402 is a porogen-containing SLAM. For example, the SLAM can be a siloxane-based spin-on-glass (SOG) that contains a light absorbing dye. The dye content can be adjusted to provide the absorption required by the trench lithography process. Spin-on SLAMs can be deposited using a conventional spin-coat of siloxanes in an appropriate solvent and then baked to chemically condense the siloxane molecules and thereby form a dense porogen-containing SLAM network that has a thickness in a range of 25-200 nm over the upper surface 404 of the ILD 198.

Next, as shown in FIG. 5, resist layer 502 is patterned over the upper surface of the antireflective/fill material 402. The resist has been patterned to form an opening 504 that exposes portions of antireflective/fill material 402. Next, exposed portions of antireflective/fill material 402 can be removed using a conventional fluorine-based oxide plasma etch process (or in the case wherein the ILD 108 and/or the SLAM is a polymer, using an oxygen-containing plasma etch process). The etch removes antireflective/fill material 402 exposed by the opening 504. Upon reaching the upper surface 404 of the ILD 108, etching continues, and both ILD portions 510 and via portions containing antireflective/fill material 402 are etched simultaneously until a trench (here indicated by the dashed line 506) is formed. One of ordinary skill appreciates that the more closely the ILD 108 and the antireflective/fill material 402 etch rates match each other, the more closely the outline of the trench opening will approximate the trench outline 506 shown in FIG. 5.

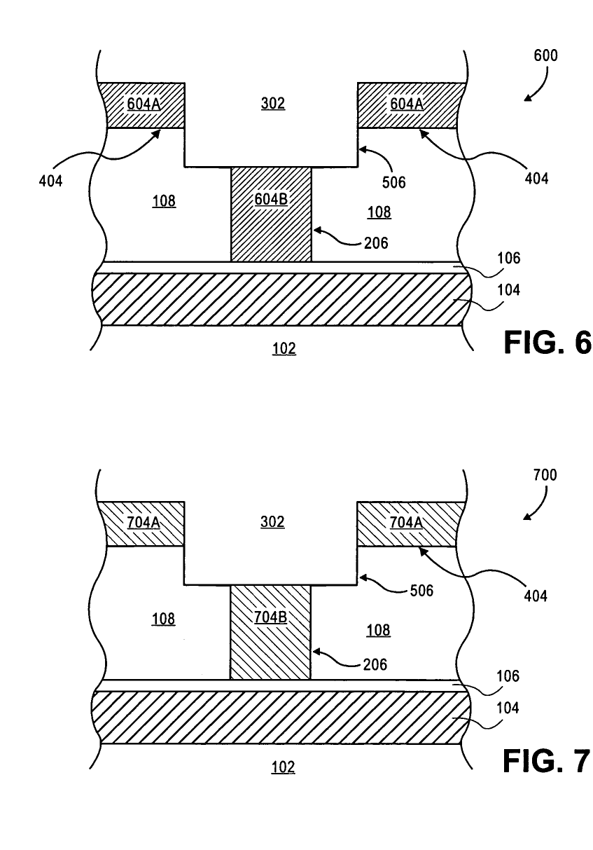

After forming the trench opening 506, the patterned resist layer 502 can be removed using conventional ash or wet clean processes. As shown in FIG. 6, SLAM portions 604A can remain over the upper surface of the ILD 108 and SLAM portion 604B can remain in the via opening 206. In conventional processing, the next step would be to remove the SLAM portions 604A and 604B using conventional cleaning processes. However, because now the ILD 108 is a porous ILD, the etch rate difference between the SLAM and the ILD is not great enough to remove the SLAM without substantially attacking the ILD 108.

In accordance with one embodiment of the present invention, the SLAM is deposited initially having a first physical and/or chemical property and then prior to removing the SLAM, the physical and/or chemical property is changed to facilitate its removal. In accordance with one embodiment, the SLAM is deposited initially having a first density. Then, prior to removing it, the SLAM (portions 604A and 604B) can be cured in such as way to induce porosity into it. In this way, the etch rate of the SLAM can be increased to the extent that it can be removed selectively with respect to the porous ILD 108.

SLAM porosity can be induced by incorporating a sacrificial porogen agent into the liquid SLAM solution prior to it being spun-on the semiconductor substrate (in alternative embodiments, where the SLAM is deposited using a chemical vapor deposition process, the porogen can be introduced in-situ as a CVD precursor). After being deposited over the surface of dielectric 108 and within via opening 206, the SLAM is cured. Curing changes porosity of the SLAM and makes it less dense. Curing can occur before or during photolithography or before, during, or after etch, depending on the impact that the cure has on the SLAM's light absorbing and etch characteristics.

For, example, in embodiments where curing changes the etch rate of the SLAM (i.e., region 402B in FIG. 5) to a point where it is significantly different that the etch rate of the dielectric regions 510 (FIG. 5), then it may be advantageous to wait until after the trench is formed to cure the SLAM. In embodiments, where curing helps to more closely match the etch rates of the two materials or does not impact the SLAM etch rate, then it may be advantageous to cure the SLAM prior to etch. And, to the extent that the porogen does not negatively impact the SLAM's ability to absorb light, then it may be advantageous to cure the SLAM before or during the trench photolithography process.

SLAM curing can be accomplished by thermal curing, e-beam curing, ultra-violet light curing, chemical curing (removal of porogen chemically), or the like. Curing promotes degradation and volatilization or solubilization, as the case may be, of the porogen and results in a network of nanopores (pores in the ILD formed by the removal of the porogen) embedded in the SLAM matrix. The wet chemical etch rate of the SLAM and the selectivity of the SLAM to the ILD 108 are influenced by the size and the density of the nanopores. In the case of e-beam curing, the porogen can be a carbon-based material, such as a diene, a poly(ethylene oxide) (PEO) surfactant, a poly(propylene oxide) (PPO) surfactant, a pluronic surfactant or a Brij surfactant.

In the case of thermal curing, the porogen can be a polyoxymethylene-type or a norbornene-type material (which typically can have thermal decomposition temperatures in a range of approximately 250-400 degrees Celsius). In the case of thermal curing, the porogen can also include oligomers of the following polymers (which can thermally decompose at temperatures in a range of approximately 250-410 degrees Celsius): Poly propylene oxide (PPO), Polymethylstyrene (PMS), Polyoxymethlene (POM), Polycaprolactone, Polycarbonate, Polyamideimide (PAI), Polyamide-6,6, Polyphthalamide (PPA), Polyetherketone (PEK), Polyethretherketone (PEEK), Poly (butylene terephthalate) (PBT), Poly (ethylene terephthalate) (PET), Polystyrene (PS), Polystyrene-syndiotactic (PS-syndiotactic), Polyphenylene Sulfide (PPS), Polyether Sulfone (PES). One of ordinary skill appreciates that the foregoing list of porogens is non-exhaustive and that other porogen material types can be used in order to practice embodiments of the present invention.

In FIG. 7, the SLAM has been cured and regions 604A and 604B have been converted to a material 704A and 704B that has different physical properties, chemical properties, or combinations thereof, as compared to regions 604A and 604B. In one embodiment, the material of 704A and 704B is more porous than the SLAM material that was originally deposited over the substrate surface (i.e., the dense SLAM material). In an alternative embodiment, the post-cure porosity of regions 704A and 704B is greater than the porosity of the regions 604A and 604B. In yet another embodiment, the post-cure porosity of the SLAM is greater than the porosity of the porous dielectric layer 108. One of ordinary skill appreciates that the amount of post-cure SLAM porosity is a matter of degree and that the amount of porosity required by the post-cure SLAM relative to it pre-cure porosity or the porosity of other films can additionally depend on the processes and materials used to remove the SLAM after it has been cured. Therefore, achieving porosity levels that permit selective removal of the portions 704A and 704B relative to the ILD 108 should be a primary consideration for those practicing embodiments of the present invention. Here, the SLAM having been converted to the less dense form is ready to be removed. Selective removal of the SLAM (with respect to the ILD 108) can now be accomplished much more easily.

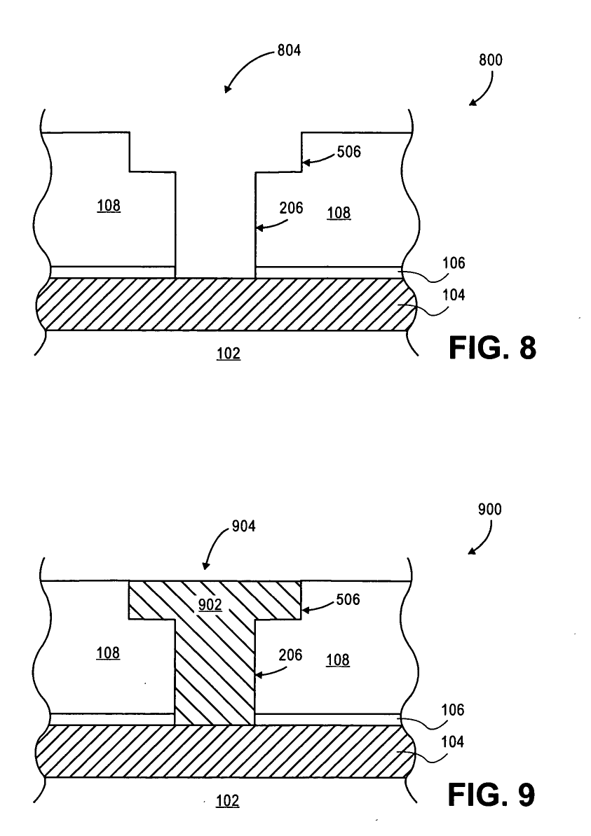

As shown in FIG. 8 the SLAM has been removed. Unlike conventional SLAMs, the SLAM disclosed herein can be removed with reduced attack of the porous ILD using a wet, dry or combination wet/dry removal process. In accordance with one embodiment, the SLAM can be removed using solvents containing fluoride ions and/or solvent-based mixtures of hydroxides. In alternate embodiments, SLAM removal can occur via thermal decomposition, or via curing using e-beam or ultraviolet systems. After removing the SLAM, exposed portions of optional ESL 106 can be removed using a conventional plasma etch process to expose portions of the underlying conductive layer 104. Then the underlying conductive material can be cleaned using conventional processing to remove any remaining etch residue.

In FIG. 9 a conductive material 902 has been deposited in trench 506 and via 206. The combination via/trench forms a dual-damascene interconnect 904. The dual-damascene interconnect 904 includes conductive material 902. The conductive material 902 can include: (1) barrier layers, such as tantalum nitride (TaN), titanium nitride (TiN), titanium. tungsten (Ti/W), composites thereof, or the like; (2) seed layers that comprise copper, metallic, or copper-alloy seed materials; and (3) bulk conductive materials, that can include copper, aluminum, or alloys of copper or aluminum, or the like. Typically a combination of barrier, seed, and bulk conductive materials fill the dual-damascene opening. Excess conductive fill material can then be removed using chemical-mechanical-planarization to form the dual-damascene structure shown in FIG. 9. Processing thereafter is considered conventional to one of ordinary skill in the art. Additional layers of interconnects, ILD's, bond pad structures, etc., may be formed to fabricate a semiconductor device.

Conventional SLAMs, while generally considered non-porous, can be difficult to remove selectively in the presence of porous ILDs. Embodiments of the present invention overcome this limitation by using a relatively dense SLAM to pattern a trench opening in a resist layer. And then, after the trench pattern has been defined, the relatively dense SLAM is converted into a SLAM which is more porous. Changing the SLAM's porosity facilitates its removal in the presence of a porous ILD. While embodiments of the present specification disclose using the cure-assisted SLAM for via-first trench-last dual-damascene patterning, one of ordinary skill appreciates that embodiments disclosed herein are also suitable for use in trench-first via-last dual-damascene patterning applications.

The various implementations described above have been presented by way of example only and not limitation. Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method for forming a semiconductor device comprising:
forming an anti-reflective coating (ARC) over a substrate;
etching a feature in the substrate;
changing a property of the ARC; and
removing the ARC.

2. The method of claim 1 further comprising:
forming a dielectric layer over the substrate, wherein the dielectric layer has a bottom side closer to the substrate and a top side opposite the bottom side;
forming a first opening in the dielectric layer prior to forming the ARC, wherein the ARC fills the first opening and covers at least portions of the top side patterning a resist layer over the ARC;
removing ARC material and portions of the dielectric layer during etching to form a second opening in the dielectric layer, wherein portions of the second opening overlie portions of the first opening; and
removing the resist layer before changing a property of the ARC.

3. The method of claim 2, wherein forming a dielectric layer over the substrate is further characterized as forming a porous interlevel dielectric layer over the substrate.

4. The method of claim 3, wherein:
forming the ARC over the substrate is further characterized as a forming a Sacrificial Light Absorbing Material (SLAM) over the substrate; and
changing a property of the ARC changes the ARC from being less porous to more porous.

5. The method of claim 4, wherein after changing the property of the ARC, a porosity of the ARC is greater than a porosity of the dielectric layer.

6. The method of claim 5, wherein the porosity of the ARC is changed via a process selected from a group consisting of thermal curing, e-beam curing, ultraviolet light curing, and chemical curing.

7. The method of claim 5, wherein the porosity of the ARC is changed via thermal curing.

8. The method of claim 4, wherein removing the ARC removes ARC portions over the top side and ARC portions in the first opening.

9. The method of claim 8, wherein forming a first opening forms a via portion of a dual-damascene structure and wherein removing ARC material and portions of the dielectric layer during etching forms a trench portion of the dual-damascene structure.

10. The method of claim 9 further comprising filling the dual-damascene structure with a conductive material.

11. The method of claim 10 further comprising removing portions of an etch stop layer overlying the conductive material exposed by the via portion before filling the dual-damascene structure.

12. A method for forming a semiconductor device comprising:
forming a Sacrificial Light Absorbing Material (SLAM) over an interlevel dielectric (ILD) layer having a via opening;
patterning a trench opening in a resist layer over the SLAM, wherein at least a portion of the trench opening overlies a portion of the via opening;
etching regions exposed by the trench opening including portions of the SLAM and the ILD to form a trench;
changing a property of the SLAM;
removing the SLAM;
filling a dual-damascene structure defined by removal of the SLAM with a conductive fill material.

13. The method of claim 12, wherein the ILD is further characterized as one of a low-k material, an ultra low-k material and a mesoporous material.

14. The method of claim 13, wherein changing a property of the SLAM is further characterized as changing the porosity of the SLAM.

15. The method of claim 13, wherein changing the porosity of the SLAM is further characterized as changing the porosity of the SLAM so that it is more porous than the ILD.

16. The method of claim 14, wherein changing a property of the SLAM occurs before patterning a trench opening.

17. The method of claim 14, wherein changing a property of the SLAM occurs before etching regions exposed by the trench opening.

18. The method of claim 14, wherein changing a property of the SLAM occurs after etching regions exposed by the trench opening.

19. The method of claim 13, wherein changing a property of the SLAM is accomplished by incorporating porogens into the SLAM and then removing the porogens.

20. The method of claim 19, wherein removing the porogens is accomplished by one of thermal curing or e-beam curing.

21. A semiconductor device that includes a damascene structure formed in an interlevel dielectric layer (ILD) using a Sacrificial Light Absorbing Material (SLAM), wherein a property of the SLAM is changed prior to a removal of the SLAM.

22. The semiconductor device of claim 21, wherein the property is further characterized as a porosity of the SLAM.

23. The semiconductor device of claim 21, wherein the removal of the SLAM is accomplished using one of thermal curing or e-beam curing.

24. The method of claim 23, wherein the ILD is further characterized as one of a low-k material, an ultra low-k material, and a mesoporous material.

25. The method of claim 24, wherein changing a property of the SLAM is accomplished by incorporating porogens into the ILD and then removing the porogens.

26. A method for forming a semiconductor device comprising:
forming an anti-reflective coating (ARC) over a dielectric and within a first feature opening in the dielectric;
etching a second feature opening in the dielectric, wherein etching the second feature opening comprises removing portions of the ARC in the first opening and portions of the dielectric;
changing a property of the ARC; and
removing the ARC.

27. The method of claim 26, wherein the ARC is further characterized as a Sacrificial Light Absorbing Material.

28. The method of claim 27, wherein the first feature opening is further characterized as a via portion of a dual-damascene opening and the second feature opening is further characterized as a trench portion of the dual damascene opening.

29. The method of claim 27, wherein the first feature opening is further characterized as a trench portion of a dual-damascene opening and the second feature opening is further characterized as a via portion of the dual damascene opening.
